(19) United States
(12) Patent Application Publication
(10) Pub. No.: US 2006/0151878 A1
(43) Pub. Date: Jul. 13, 2006

(54) Semiconductor chip packaging apparatus and method of manufacturing semiconductor chip package

(76) Inventors: Se-Young Jeong, Seoul (KR); Nam-Seog Kim, Yongin-si (KR); Sung-Ki Lee, Seoul (KR); Hee-Kook Choi, Seoul (KR); Ki-Kwon Jeong, Cheonan-si (KR); Tae-Sung Park, Cheonan-si (KR); Yoshikuni Nakadaira, Suwon-si (KR); Sang-Hyeop Lee, Cheonan-si (KR); Sung-Hwan Kim, Cheonan-si (KR)

Correspondence Address: HARNESS, DICKEY & PIERCE, P.L.C., P.O. BOX 8910, RESTON, VA, 20195, US

(21) Appl. No.: 11/326,192

(22) Filed: Jan. 6, 2006

(30) Foreign Application Priority Data
Jan. 8, 2005 (JP) 10-2005-0001950

(51) Int. Cl. H01L 23/48

(52) U.S. Cl. 257/737

(57) ABSTRACT

Example embodiments of a semiconductor chip packaging apparatus and method thereof are disclosed. The packaging apparatus may include a plating unit to perform a conductive plating process to form a conductive plating layer on external terminals of a semiconductor chip package, and a reflow unit adapted to melt the conductive plating layer. The plating unit and reflow unit may be disposed in a single line with the plating module. Thus, it is possible to effectively suppress the growth of whiskers on the plating layer of the external terminals, and to secure economical efficiency, reducing costs, and allowing mass production.

### PRIORITY CLAIM

A claim of priority is made to Korean Patent Application No. 10-2005-0001950, filed on Jan. 8, 2005, in the Korean Intellectual Property Office, the disclosure of which is incorporated herein in its entirety by reference.

### BACKGROUND OF THE INVENTION

1. Field of the Invention

Example embodiments of the present invention relate to a semiconductor chip packaging apparatus and a method of manufacturing a semiconductor chip package. More particularly, example embodiments of the present invention relate to an apparatus adapted to finish-processing semiconductor chip packages.

2. Description of the Related Art

In an example process of packaging a semiconductor chip, a semiconductor chip is attached to a package substrate and molded within a frame to protect it from external stimulations, e.g., conditions. Then, external terminals (leads) are connected to electrode pads of the semiconductor chip to connect the semiconductor chip to external electronic devices.

First on a wafer level, a semiconductor wafer is cut into individual semiconductor chips by a sawing process. The individual semiconductor chips are then attached to a printed circuit board (PCB) having external terminals, e.g., a lead frame. In a subsequent wire-bonding process, wires attach the electrode pads of a semiconductor chip to the external terminals. A molding process is then performed to protect the semiconductor chip.

As a final manufacturing process on the semiconductor chip package and to increase the reliability of the electrical connections between the external terminals and the external electronic devices, a finish-processing is performed. A finish-processing may refer to a process of forming a plating layer composed of a lead (Pb) or lead-containing tin (Sn) alloy on the external terminals.

However, the lead contained in the plating layer is known to be harmful to the human body. Further, electronic devices containing leads cause pollution and environmental hazards when they are disposed. Accordingly, environment-friendly products without lead are a requirement. The “Restriction of Hazardous Substances (ROHS) directive” has been issued by the European Union (EU) to restrict the use of component materials harmful to the human body and the environment, and will go into effect on July of 2006.

Tin (Sn) or a tin alloy without lead plating layer has been suggested as a substitute plating layer. However, whiskers are generated when plating external terminals with tin or a tin alloy without lead. The whiskers may cause the leads to fail, which may cause the semiconductor chip to short-circuit.

FIG. 1 is an electron microscope image of a cross sectional view of a lead 55 of a conventional semiconductor chip package. Referring to FIG. 1, a blow-up view of region al clearly shows whiskers 57. The whiskers 57 may cause the lead 55 to fail. Accordingly, the whiskers 57 generated on the surface of the lead 55 may cause the semiconductor chip to short-circuit and malfunction.

One reason for the generation of the whiskers 57 on the surfaces of the leads 55 may be the compressive stress applied to the tin or tin alloy plating layer. The generation of the whiskers 57 may be reduced or minimized by decreasing the applied compressive stress or by converting the compressive stress into tensile stress. For example, performing a heat treatment after the plating process, adjusting the physical property of the plating layer by optimizing the plating solution, or by forming an underlying layer of a third metal, such as nickel (Ni), silver (Ag), zinc Zn or the like, between a substrate, e.g., a lead frame, and a plating layer, may reduce the generation of the whiskers 57.

Performing the heat treatment after plating has been favored because of its simplicity. The heat treatment is performed using a separate heat treatment apparatus. After the finishing process, the semiconductor chip package is laid on a separate plastic tray, transferred to the heating apparatus, and the heat treatment is performed. For example, when a lead frame is used as the external terminals, heat treatment to suppress the growth of whiskers 57 is carried out at a temperature of about 150 to 175° C. for about 1 to 2 hours.

However, the addition of heat treatment process may have the following problems in mass production. First, a separate and additional heat treatment process may reduce product yield. Second, investment in production cost may increase due to the need to purchase the heat treatment equipment and the addition and need for space for an apparatus line. For example, substituting a 150° C. tray for the current 130° C. tray may increase production cost. Third, the heat treatment process may only suppresses the whiskers 57 to a small extent for certain type of lead frames.

### SUMMARY OF THE INVENTION

Example embodiments of the present invention provide a semiconductor chip packaging apparatus capable of effectively suppressing the growth of whiskers in leads of semiconductor device. [000131 In an embodiment of the present invention, a semiconductor chip packaging apparatus includes a plating unit adapted to form a conductive plating layer on external terminals of a semiconductor chip package, and a reflow unit adapted to melt the plating layer and configured in a line with the plating unit.

In another embodiment of the present invention, a method of finish-processing a semiconductor chip package includes forming a conductive plating layer on external terminals of the semiconductor chip package, and melting and reflowing the conductive plating layer. The forming the plating layer and the reflowing the plating layer may be successively performed in an apparatus having a plating unit and a reflow unit arranged along a line.

### BRIEF DESCRIPTION OF THE DRAWINGS

The present invention will become more apparent with the description of example embodiments thereof with reference to the attached drawings in which:

FIG. 1 is electron microscope image of a cross sectional view of leads of a conventional semiconductor chip package after a finish-process;

FIG. 2 is a schematic diagram of a semiconductor chip packaging apparatus for a finish-process according to an embodiment of the present invention;

FIG. 3 is a schematic diagram of a semiconductor chip packaging apparatus for a finish-process according to another embodiment of the present invention;

FIG. 4 is a perspective view of a reflow unit of the semiconductor chip packaging apparatus illustrated in FIG. 1;

FIG. 5 is a flow chart illustrating a semiconductor chip packaging method of a finish-process according to an embodiment of the present invention;

FIGS. 6 through 9 are schematic diagrams illustrating a semiconductor chip packaging method of a finish-process;

FIG. 10 is a graph of a whisker length of a lead frame according to a number of finish heat treatment cycles; and

FIG. 11 is an electron microscope image of a lead frame manufactured by an embodiment of the present invention.

### DETAILED DESCRIPTION OF THE EXAMPLE EMBODIMENTS

The present invention will now be described more fully hereinafter with reference to the accompanying drawings, in which example embodiments of the present invention are described. The present invention may, however, be embodied in many different forms and should not be construed as being limited to the embodiments set forth herein. Rather, these embodiments are provided as working examples. Like numbers refer to like elements throughout the specification.

FIG. 2 is a schematic diagram of a semiconductor chip packaging apparatus 100 for a finish-processing according to an embodiment of the present invention.

Referring to FIG. 2, the packaging apparatus 100 may include a plating unit 130 and a reflow unit 160. The packaging apparatus 100 may be used to finish a semiconductor chip package 110. In general, a semiconductor chip package 110 may be used to connect to another electronic product, therefore, a finish-processing may increase contact reliability between the semiconductor chip package 110 and the electronic product. More specifically, the finish-processing may be a post-processing performed after forming a conductive plating layer (not shown) on external terminals (115 of FIG. 4).

A plating unit 130 may serve as a unit adapted to perform a process to form a conductive plating layer on the external terminals (115 of FIG. 4) of the semiconductor chip package 110. The conductive plating layer may be a tin (Sn) layer or a lead-free tin alloy layer (Sn alloy layer). The tin layer or Sn alloy layer being environmental-friendly and which satisfies the RoHS directive of the European Union (EU). For example, the tin alloy layer may be formed of SnCu, SnBi, SnAg, SnZn, or a combination thereof. In the example embodiments of the present invention, any reference to the tin alloy layer or a lead-free tin alloy means a layer substantially without lead.

A reflow unit 160 is a unit, which is adapted to perform a manufacturing, to increase the reliability of the conductive plating layer. For example, the reflow unit 160 may be used to melt the conductive plating layer to suppress the generation of whiskers. In this case, the plating unit 130 and the reflow unit 160 are arranged in a line along a direction x.

Accordingly, forming the conductive plating layer and performing a reflow-processing on the conductive plating layer may be successively performed. That is, it may be unnecessary to perform a reflow-processing in a separate apparatus after the formation of the conductive plating layer. Example embodiments of the present invention also may make it unnecessary to exchange current transport trays.

As shown in FIG. 2, the packaging apparatus 100 may further include a transporting device 120 to transport a semiconductor chip package 110 from the plating unit 130 to the reflow unit 160. For example, the transporting device 120 may be a conveyer belt system or any type of device capable of transporting electronic devices from one area to another. The transporting device 120 attaches the semiconductor chip package 110 thereto for transportation.

The reflow unit 160 will now be described in greater detail with reference to FIG. 4. Referring to FIG. 4, the reflow unit 160 may include a heating device 165 adapted to melt the conductive plating layer of the semiconductor chip package 110.

A heating device 165, which may be a device capable of emitting infrared rays, deep infrared rays, hot air, or a mixture thereof, as indicated by arrows 168. For example, the heating device 165 may be adapted to simultaneously emit infrared rays and hot air; infrared rays and deep infrared ray; deep infrared rays and hot air; or infrared rays, deep infrared rays, and hot air.

The transporting device 120 may pass through the reflow unit 160 with the semiconductor chip package 110 attached thereto. The semiconductor chip package 110 may have a number of semiconductor chips attached to a package frame, for example, a lead frame 115. The package frame may be a printed circuit board having another type of external terminals other than the lead frame 115 having leads. For example, the package frame may be a printed circuit board having solder balls as the external terminals.

A plating layer (not shown) of the external terminals 115 is heated and melted while the semiconductor chip package 110 passes through the heating device 165. A heating time may be determined based on a speed at which the transporting device 120 moves and/or a length L of the reflow unit 160. For example, when the speed of the transporting device 120 is determined, the length L of the reflow unit 160 may be varied to determine the amount of heat necessary to be applied to the conductive plating layer.

The length L of the reflow unit 160 may be at least about 0.75 cm to ensure that sufficient (minimum) amount of heat necessary to melt the surface of the tin plating layer or the tin alloy plating layer is irradiated thereon. Further, the heating time should be adjusted so that the melted conductive plating layer does not flow down. In other words, the melted conductive plating layer does not flow off the external terminals. Accordingly, the length L of the reflow unit 160 may be less than about 450 cm.

In an example embodiment, the reflow unit 160 may be a modified conventional finish-processing device. For example, changing a conventional hot air dryer (not shown) into the reflow unit 160 may reduce costs. A first type of hot air dryer having a length of about 64 cm and a second type of hot air dryer having a length of about 30 cm may be used as the reflow unit 160. Hence, the length L of the reflow unit 160 may range from about 30 to 75 cm to accommodate various hot air dryer.

Further, the reflow unit 160 may be arranged in a line having an existing plating unit. Accordingly, costs related to fabricating a separate finish device in which the plating unit and the reflow unit are arranged in a line with each other may be avoided.

As illustrated in FIG.4, the reflow unit 160 may further include a gas flow system 170 for atmospheric control. In this example embodiment, an inflow of gas(es) serves to reduce or prevent the external terminals 115 from being oxidized during the reflow process. The gas may be an inert gas, such as nitrogen, or hydrogen to form a reduce atmosphere.

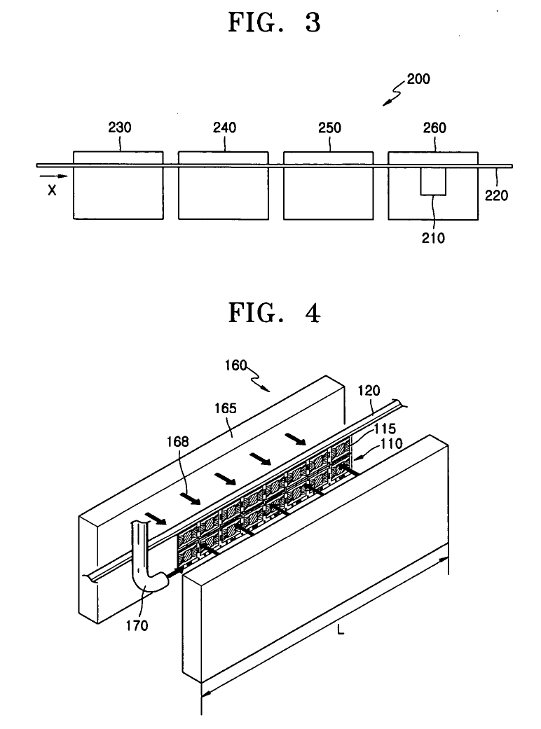

FIG. 3 is a schematic diagram of a semiconductor chip packaging apparatus 200 for a finish-processing according to another embodiment of the present invention. The semiconductor chip packaging apparatus 200 further includes a cleaning unit 240 and a drying unit 250 between a plating unit 230 and a reflow unit 260. The plating unit 230 and the reflow unit 260 are similar to the semiconductor chip packaging apparatus 100 of FIG. 2, therefore, detail descriptions thereof are omitted.

Referring to FIG. 3, the plating unit 230, the cleaning unit 240, the drying unit 250, and the reflow unit 260 are arranged in a single line along a first direction. A transporting device 220 may be a belt system or other similar transporting device. The transporting device 220 extends from the plating unit 230 to the cleaning unit 240, the drying unit 250, and the reflow unit 260. Accordingly, a semiconductor chip package 210 attached to the transporting device 220 sequentially passes through the plating unit 230 to the reflow unit 260.

The cleaning unit 240 may clean the semiconductor chip package 210 after a conductive plating process is completed on the semiconductor chip package 210. For example, the cleaning unit 240 may clean the semiconductor chip package 210 with water or any other common cleaning solution.

The drying unit 250 dries the semiconductor chip package 210 when cleaning is completed. For example, the drying unit 250 may use air or hot air as a drying device. Alternatively, the drying unit 250 may use a heating device such as an infrared device.

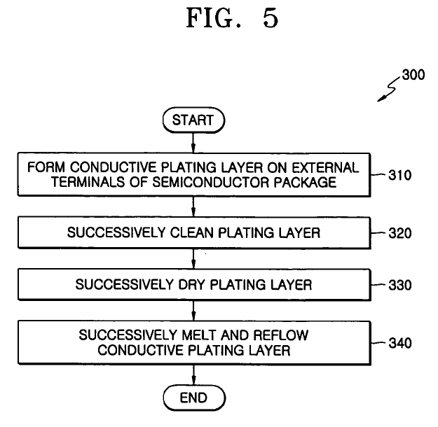

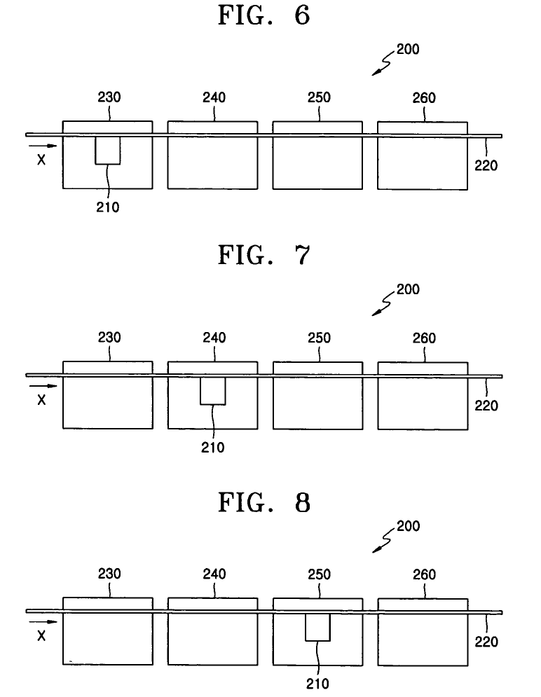

FIG. 5 is a flow chart illustrating a semiconductor chip packaging method 300 of a finish-processing according to an embodiment of the present invention. The semiconductor chip packaging method 300 will be described in greater detail also with FIGS. 6 through 9. Here, different stages of the semiconductor chip packaging method using the semiconductor chip packaging apparatus 200 are exemplarily illustrated in FIGS. 6 through 9.

to FIG. 6, a conductive plating layer may be formed on the external terminals of the semiconductor chip package 210 (S310 of FIG. 5). Specifically, the transporting device 220 having the semiconductor chip package 210 thereon moves into the plating unit 230. The plating unit 230 may uses a plating solution to plate the external terminals. The plating solution may be a tin solution or a tin alloy solution. For example, the tin alloy may be SnCu, SnBi, SnAg or SnZn.

Referring to FIG. 7, after the conductive plating layer is formed on the external terminals, the semiconductor chip package 210 is cleaned (S320 of FIG. 5). For example, the transporting device 220 moves the semiconductor chip package 210 from the plating unit 230 to the cleaning unit 240. The cleaning unit 240 uses a cleaning solution such as water to clean the semiconductor chip package 210. The semiconductor chip package 210 may be moved into the cleaning unit 240 and then cleaned, or the semiconductor chip package 210 may be simultaneously cleaned while passing through the cleaning unit 240.

The cleaning process serves to remove any remaining plating solution that did not adhere to the external terminals, or may remove other impurities. The cleaning process ensures contact reliability by removing the impurities, because the impurities degrade the contact between the external terminals and the electronic product.

Referring to FIG. 8, after the cleaning the semiconductor chip package 210, the conductive plating layer is dried (S330 of FIG. 5). For example, the transporting device 220 transports the semiconductor chip package 210 from the cleaning unit 240 to the drying unit 250. In the drying unit 250, for example, compressed air may come from a wall of the drying unit 250 to dry the semiconductor chip package 210. The semiconductor chip package 210 may be moved into the drying unit 250 and then dried, or the semiconductor chip package 210 may be simultaneously dried while passing through the drying unit 250.

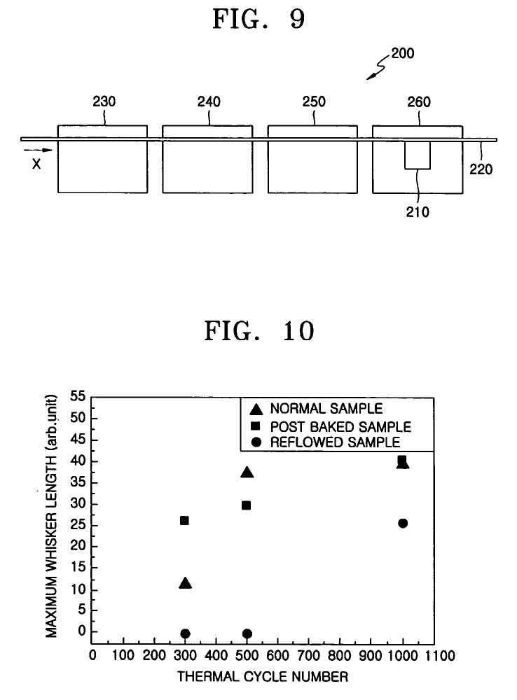

Referring to FIG. 9, a reflow processing is performed by melting the conductive plating layer of the semiconductor chip package 210 (S340 of FIG. 5). For example, the transporting device 220 may transport the semiconductor chip package 210 from the drying unit 250 to the reflow unit 260.

A heating device (see 165 of FIG. 4) may be disposed on a wall of the reflow unit 260 to melt the conductive plating layer formed on a surface of the external terminals. The heating device may heat the plating layer surface by emitting infrared rays, deep infrared rays, hot air, or a combination thereof.

A reflowing temperature may range from about 210 to 450° C. to melt the conductive plating layer. The temperature may be limited to less than about 280° C. so that the melted tin or tin alloy plating layer does not flow down. In addition, when the semiconductor chip package 210 is heated while passing through the reflow unit 260, the temperature may be restricted to about 250° C. or more to ensure that the minimum heat needed to melt the conductive plating layer is obtained. The temperature may be in a range from about 250 to 280° C.

The heating treatment in the reflow process (S340 of FIG. 5), e.g., the reflow of the external terminals may be affected by the speed of the transporting device 220, as well as by temperature. A reflow processing time may range from about 0.1 to 60 seconds depending on the speed of the transporting device 220. The package may be heated for 4 to 10 seconds to melt the conductive plating layer of the external terminals without having the conductive plating layer flow down. Thus, the speed of the transporting device 220 may be determined by the length of the reflow unit 260, the temperature, and the heating time.

Further, the reflow process (S340 of FIG. 5) may be performed under an inert atmosphere or a reducing atmosphere to reduce or prevent the plating layer from being oxidized. For example, the reflow operation may be performed under inert nitrogen or a reducing hydrogen atmosphere.

As described in FIGS. 6 through 9, a finish-processing may be performed on the semiconductor chip package 210 by successively performing a forming process (S310 of FIG. 5), a cleaning process (S320 of FIG. 5), a drying process (S330 of FIG. 5), and a reflowing process (S340 of FIG. 5) of the conductive plating layer on the semiconductor chip packaging apparatus 200.

Example embodiments of the semiconductor chip packaging apparatus 200 of the present invention are capable of performing a reflow processing along a single process line without the need of new separate equipment. Further, there is no need to exchange transport trays to perform the separate heat treatment process, which may result in cost reduction.

FIG. 10 is a graph illustrating length of whiskers of a lead frame according to a number of finish heat treatment cycles.

Referring to FIG. 10, (▴) represents a normal sample that was not separately heat-treated; (▪) represents a sample that was post baked in a separate apparatus; and (●) represents a reflowed sample subjected to a finish-processing. Maximum lengths of whiskers grown on the plating layer of the lead frame samples above were compared. The reflowed sample (●) was reflowed in a separate reflow apparatus to confirm the effects of the example embodiments of the present invention.

As can be seen from FIG. 10., in the normal sample (▴) and the baked sample (▪), whiskers having a significant length were generated after as few as 500 thermal cycles. On the other hand, the reflow-processed sample (●) had almost no whiskers after 500 thermal cycles.

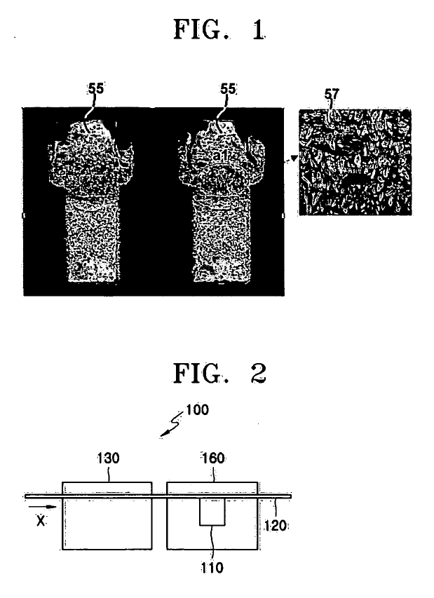

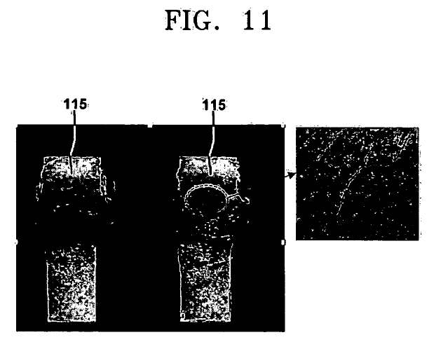

FIG. 11 is an electron microscope image of a lead frame 115 of the reflowed sample (●) after 500 thermal cycles. As can be seen from the enlarged portion a2 of the lead frame 115, no detectable whiskers were generated as compared with the whiskers 57 generated in the lead frame illustrated in FIG. 1.

In a reflow processing performed by the example embodiments of the semiconductor chip packaging apparatus of the present invention, whiskers may be effectively reduced or prevented from being generated on a plating layer of a lead frame formed of tin or a lead-free tin alloy. Therefore, by performing a finishing-processing, for example, from a plating process (S310 of FIG. 5) to a reflow process (S340 of FIG. 5) without transporting a semiconductor chip package to a separate apparatus, it may be possible to effectively suppress the generation of whiskers on the plating layer formed of tin or the lead-free tin alloy layer.

In another embodiment of the present invention, a reflow process is performed successively and directly after a plating process. In this case, the plating process and the reflow process are similar to those in the finish-processing according to the above-described embodiment.

While the example embodiments of the present invention have been particularly shown and described with reference to drawings, it will be understood by those of ordinary skill in the art that various changes in form and details may be made therein without departing from the scope of the present invention.

What is claimed is:

1. A semiconductor chip packaging apparatus, comprising:
a plating unit adapted to form a conductive plating layer on external terminals of a semiconductor chip package; and
a reflow unit adapted to melt the plating layer and configured in a line with the plating unit.

2. The apparatus according to claim 1, wherein the reflow unit includes a heating device.

3. The apparatus according to claim 2, wherein the heating device emits one of infrared rays, deep infrared rays, hot air or a combination thereof.

4. The apparatus according to claim 1, wherein a length of the reflow unit is in a range of about 0.75 to 450 cm in the direction of the line.

5. The apparatus according to claim 4, wherein the length of the reflow unit is in a range of about 30 to 75 cm.

6. The apparatus according to claim 1, wherein the plating layer is a tin layer or a lead-free tin alloy layer.

7. The apparatus according to claim 6, wherein the tin alloy layer is SnCu, SnBi, SnAg or SnZn.

8. The apparatus according to claim 1, wherein the reflow unit includes a gas flow device to control an atmosphere within the reflow unit.

9. The apparatus according to claim 8, wherein the gas flow device injects an inert gas or a reducing gas.

10. The apparatus according to claim 1, further including a cleaning unit adapted to clean the plating layer and configured between the plating unit and the reflow unit.

11. The apparatus according to claim 10, further including a drying unit adapted to dry the plating layer and configured between the cleaning unit and the reflow unit.

12. The apparatus according to claim 1, further including a transporting device configured to transport the semiconductor chip package in the line between the plating unit and the reflow unit.

13. The apparatus according to claim 12, further including a cleaning unit adapted to clean the plating layer and configured between the plating unit and the reflow unit.

14. The apparatus according to claim 13, further including a drying unit adapted to dry the plating layer and configured between the cleaning unit and the reflow unit.

15. The apparatus according to claim 12, wherein the transporting device is a conveyer belt system.

16. The apparatus according to claim 1, wherein the apparatus is used for finish-processing the semiconductor chip packages.

17. A method of finish-processing a semiconductor chip package, comprising:
forming a conductive plating layer on external terminals of the semiconductor chip package; and
melting and reflowing the conductive plating layer, wherein the forming the plating layer and the reflowing the plating layer are successively performed in an apparatus having a plating unit and a reflow unit arranged along a line.

18. The method according to claim 17, wherein the forming the plating layer includes plating a lead-free tin layer or a tin alloy layer on the external terminals.

19. The method according to claim 18, wherein the tin alloy is SnCu, SnBi, SnAg or SnZn.

20. The method according to claim 17, wherein the reflowing is performed by heating the semiconductor chip package.

21. The method according to claim 20, wherein the heating comprises emitting infrared rays, deep infrared rays, hot air, or a combination thereof.

22. The method according to claim 17, wherein the reflowing is performed at a temperature about 210 to 450° C.

23. The method according to claim 22, wherein the reflowing is performed at a temperature of 250 to 280° C.

24. The method according to claim 22, wherein the reflowing is performed for 0.1 to 60 seconds.

25. The method according to claim 24, wherein the reflowing is performed for 4 to 10 seconds.

26. The method according to claim 17, wherein the reflowing is performed with an inert gas or a reducing gas.

27. The method according to claim 26, wherein the gas is nitrogen gas or hydrogen gas.

28. The method accordingly to claim 17 further including:
cleaning the plating layer; and
drying the plating layer, wherein the forming, the cleaning, the drying and the reflowing are successively performed in an apparatus having the plating unit, the reflow unit, a cleaning unit, and a drying unit arranged along a line.
